(19) United States
(12) Patent Application Publication
(10) Pub. No.: US 2025/0201953 A1
(43) Pub. Date: Jun. 19, 2025

(54) STORAGE BATTERY, BATTERY UNIT AND BATTERY MONITORING DEVICE

(71) Applicant: DENSO CORPORATION, Kariya-city (JP)

(72) Inventor: Minoru OKAMIYA, Kariya-city (JP)

(73) Assignee: DENSO CORPORATION, Kariya-city (JP)

(21) Appl. No.: 19/068,215

(22) Filed: Mar. 3, 2025

Related U.S. Application Data
(63) Continuation of application No. PCT/JP2023/014875, filed on Apr. 12, 2023.

(30) Foreign Application Priority Data
Sep. 1, 2022 (JP) 2022-139443

(51) Int. Cl. H01M 10/48; G01R 27/26; H01M 10/0525; H01M 10/0587; H01M 50/431; H01M 50/489

(52) U.S. Cl. CPC H01M 10/486; G01R 27/2623; H01M 10/0525; H01M 10/0587; H01M 50/431; H01M 50/489

(57) ABSTRACT

A storage battery includes a positive electrode layer, a negative electrode layer, and a separator disposed between the positive electrode layer and the negative electrode layer. The separator is provided in a form that includes a substance whose dielectric constant changes in response to temperature. The battery unit includes a calculation section that is configured to apply an AC signal to the positive electrode terminal and the negative electrode terminal of the storage battery and calculates the dielectric constant or capacitor capacity based on the response signal, and a temperature monitoring section that monitors the internal temperature of the storage battery based on the dielectric constant or capacitor capacity calculated by the calculation section.

### CROSS-REFERENCE TO RELATED APPLICATION

This application is the U.S. bypass application of International Application No. PCT/JP2023/014875 filed on Apr. 12, 2023 which designated the U.S. and claims priority to Japanese Patent Application No. 2022-139443 filed on Sep. 1, 2022, the contents of both of which are incorporated herein by reference.

### TECHNICAL FIELD

The present disclosure in this specification relates to a storage battery, a battery unit and a battery monitoring device.

### BACKGROUND

In the past, various technologies have been proposed for monitoring the internal temperature in storage batteries (secondary batteries) such as lithium-ion storage batteries. As such technology, for example, there is known technology that has an external surface temperature detection section that detects the external surface temperature of a storage battery, a current detection section that detects the charge/discharge current of the storage battery, and an internal resistance estimation section that estimates the internal resistance of the storage battery, and estimates the internal temperature of the storage battery based on the external surface temperature, the charge/discharge current, and the internal resistance of the storage battery (refer to JP 2018-170144 A, for example). Another known technology is to install temperature sensors only at specific positions (e.g., at both ends and at the center) of all battery cells in a battery assembly with multiple battery cells, and to estimate the temperature of a battery cell without a temperature sensor by linear interpolation of the temperature values detected by each of these temperature sensors.

### SUMMARY

In a first aspect, a storage battery includes a positive electrode layer, a negative electrode layer, and a separator disposed between the positive electrode layer and the negative electrode layer, and the separator is provided in a form that includes a substance whose dielectric constant changes in response to temperature.

In the storage battery, the separator is provided in a form that includes a substance whose dielectric constant changes in response to temperature, making it possible to detect the internal temperature of the storage battery by measuring the dielectric constant or its correlated value. In this case, for example, when a temperature change occurs inside the storage battery, the temperature change can be directly detected as a change in the dielectric constant inside the battery. As a result, it is possible to realize a storage battery that enables quick detection of the internal temperature.

### BRIEF DESCRIPTION OF THE DRAWINGS

The above features of the present disclosure will be made clearer by the following detailed description, given referring to the appended drawings. In the accompanying drawings:

FIG. 1 shows a perspective view of a storage battery;

FIG. 2 shows a perspective view of a wound body that constitutes the storage battery;

FIG. 3 shows a diagram of the temperature characteristics of the dielectric constant in ferroelectric material;

FIG. 4 shows a schematic diagram of a battery unit, including the storage battery;

FIG. 5 shows a flowchart of a storage battery temperature monitoring process;

FIGS. 6A, 6B, and 6C show the temperature characteristics of dielectric constant;

FIG. 7 shows a flowchart of a correction value calculation process in a second embodiment;

FIG. 8 shows a diagram of the temperature characteristic of relative dielectric constant in ferroelectric material;

FIGS. 9A and 9B show an example of a complex impedance plane plot of the storage battery;

FIG. 10 shows a diagram of the relationship between frequency f and the real part Re_Z;

FIG. 11 shows a diagram of an equivalent circuit of the storage battery;

FIG. 12 shows a diagram of a control unit in a third embodiment;

FIG. 13 shows a flowchart of a storage battery temperature monitoring process in the third embodiment;

FIG. 14 shows a diagram of the relationship between the real part Re_Z and the relative dielectric constant εr; and

FIG. 15 shows a flowchart of a storage battery temperature monitoring process in a variation.

### DETAILED DESCRIPTION OF THE PREFERRED EMBODIMENTS

The existing technology does not directly detect the internal temperature of the storage battery, but estimates the internal temperature by using the detected value of the external surface temperature of the storage battery, etc., and therefore, a detection delay occurs due to the time required for heat transfer from the inside to the outside surface of the storage battery. As a result, there is a concern that, for example, when temperature changes occur inside a storage battery, there may be a delay before the temperature changes can be detected. For example, thermal runaway may occur in storage batteries due to some factors, and it is desirable to take appropriate measures as soon as possible when such thermal runaway occurs.

The present disclosure has been made in light of the problems set forth above and has as its object to provide a storage battery, a battery unit, and a battery monitoring device that enable quick detection of the internal temperature.

A plurality of disclosed aspects in the present specification employ different technical means from each other to achieve their respective purposes. The objects, features, and effects disclosed in the present specification will become clearer with reference to the subsequent detailed description and accompanying drawings.

In a first aspect, a storage battery includes a positive electrode layer, a negative electrode layer, and a separator disposed between the positive electrode layer and the negative electrode layer, and
the separator is provided in a form that includes a substance whose dielectric constant changes in response to temperature.

In the storage battery, the separator is provided in a form that includes a substance whose dielectric constant changes in response to temperature, making it possible to detect the internal temperature of the storage battery by measuring the dielectric constant or its correlated value. In this case, for example, when a temperature change occurs inside the storage battery, the temperature change can be directly detected as a change in the dielectric constant inside the battery. As a result, it is possible to realize a storage battery that enables quick detection of the internal temperature.

In a second aspect, a ferroelectric material is used as the substance. In this case, the ferroelectric material is added to the separator to increase the dielectric constant and improve the sensitivity of temperature detection.

In a third aspect, the separator undergoes melting when the temperature inside the battery reaches a predetermined melting temperature, and the substance is a ferroelectric material whose Curie temperature, at which the dielectric constant reaches its maximum value, is at or near the melting temperature of the separator.

In the storage battery, processes that occur when thermal runaway occurs as the internal temperature rises include melting of the separator, thermal decomposition of the positive electrode, generation of internal gases, and thermal runaway in this order. In this case, when the internal temperature of the storage battery rises and reaches or near the melting temperature of the separator, a sudden change in the dielectric constant of the storage battery (sudden change in capacitor capacity) occurs. Here, by detecting the sudden change in dielectric constant, the situation where thermal runaway of the storage battery may occur can be quickly detected.

In a fourth aspect, there is provided a storage battery according to the first aspect, a calculation section that is configured to apply an AC signal to the positive electrode layer and the negative electrode layer and calculates the dielectric constant or capacitor capacity based on the response signal, and a temperature monitoring section that is configured to monitor the internal temperature of the storage battery based on the dielectric constant or capacitor capacity calculated by the calculation section.

In a configuration where the dielectric constant changes in response to temperature in a storage battery, the capacitor capacity between the positive electrode layer and the negative electrode layer changes in response to temperature. On the other hand, according to the electrochemical impedance measurement method (AC impedance method), the frequency characteristics of the impedance can be obtained by applying AC signals to the positive and negative electrode layers and the capacitor capacity of the storage battery can be calculated based on the impedance frequency characteristics. In this case, the dielectric constant or capacitor capacity is calculated by applying an AC signal to the positive and negative electrode layers, and the dielectric constant or capacitor capacity is used for battery monitoring, which allows the internal temperature of the storage battery to be determined suitably.

In a fifth aspect, in the storage battery, the separator undergoes melting when the battery interior reaches a predetermined melting temperature, as the substance, a ferroelectric material is used whose Curie temperature at which the dielectric constant is a maximum value is the melting temperature of the separator or a temperature near the melting temperature of the separator, and the temperature monitoring section is configured to determine, based on the dielectric constant or capacitor capacity calculated by the calculation section, that the internal temperature of the storage battery has risen to a predetermined temperature determined as the melting temperature of the separator or a temperature near the melting temperature of the separator.

In the above configuration, the dielectric constant or capacitor capacity in the storage battery can suitably determine that the internal temperature of the storage battery has risen to the melting temperature of the separator or near the melting temperature of the separator. This allows the possibility of thermal runaway of the storage battery to be detected at an early stage and appropriate measures to be taken, such as notifying the user.

In a sixth aspect, in the storage battery, the substance includes a plurality of substances with different Curie temperatures at which the dielectric constant is maximized, and a unique correlation between temperature and dielectric constant or capacitance is defined within a predetermined temperature range including between the Curie temperatures of each of the substances, and the temperature monitoring section estimates the internal temperature of the storage battery based on the dielectric constant or capacitor capacity calculated by the calculation section using the correlation.

When a plurality of substances with different Curie temperatures are added to the separator in the storage battery, it is possible to define a unique correlation between temperature and dielectric constant or capacitor capacity within a predetermined temperature range, including between the Curie temperatures of each substance. In other words, it is possible to quantify the change in dielectric constant or the change in capacitor capacity corresponding to the internal temperature of the storage battery. This correlation can then be used to estimate the internal temperature of the storage battery based on the dielectric constant or capacitor capacity.

In a seventh aspect, there is provided a temperature determination section configured to determine that the internal temperature of the storage battery and the external temperature outside the storage battery are the same under the same circumstances, and a correction value calculation section that, when it is determined that a situation exists in which the temperature of the storage battery and the external temperature are the same, calculates a correction value for correcting the correlation by comparing the external temperature in that situation with the internal temperature of the storage battery estimated by the temperature monitoring section.

For example, in a situation where a storage battery has been left for a long time, the internal temperature of the storage battery is the same as the external temperature. In this case, by comparing the internal temperature (estimated temperature) of the storage battery with the external temperature, it is possible to determine the deviation in the correlation between temperature and dielectric constant. In this regard, according to the above configuration, the accuracy of temperature estimation in storage batteries can be improved by calculating a correction value to correct the correlation and using that correction value to correct the correlation as appropriate.

In an eighth aspect, a battery monitoring device applicable to a storage battery having a positive electrode layer, a negative electrode layer, and a separator disposed between the positive electrode layer and the negative electrode layer, wherein the separator is provided in a form that includes a substance whose dielectric constant changes in response to temperature, the battery monitoring device includes:
a calculation section that is configured to apply an AC signal to the positive electrode layer and the negative electrode layer and calculates the dielectric constant or capacitor capacity based on the response signal, and
a temperature monitoring section that is configured to monitor the internal temperature of the storage battery based on the dielectric constant or capacitor capacity calculated by the calculation section.

In a configuration where the dielectric constant changes in response to temperature in a storage battery, the capacitor capacity between the positive electrode layer and the negative electrode layer changes in response to with temperature. On the other hand, according to the electrochemical impedance measurement method (AC impedance method), the frequency characteristics of the impedance can be obtained by applying AC signals to the positive and negative electrode layers and the capacitor capacity of the storage battery can be calculated based on the impedance frequency characteristics. In this case, the dielectric constant or capacitor capacity is calculated by applying an AC signal to the positive and negative electrode layers, and the dielectric constant or capacitor capacity is used for battery monitoring, which allows the internal temperature of the storage battery to be determined suitably. It also allows for quick detection of the internal temperature.

In a ninth aspect, a battery monitoring device applicable to a storage battery according to the first aspect, the battery monitoring device includes an AC signal application section that is configured to apply an AC signal to the positive electrode layer and the negative electrode layer of the storage battery at a frequency higher than the AC frequency corresponding to a zero-crossing point where an imaginary part becomes zero in the complex impedance characteristic of the storage battery, a calculation section that is configured to calculate the dielectric constant at the separator based on the response signal while the AC signal is applied by the AC signal application section, and a temperature monitoring section that is configured to monitor the internal temperature of the storage battery based on the dielectric constant calculated by the calculation section.

In the storage battery with ferroelectric material added to the separator, the dielectric constant of the ferroelectric material changes as the temperature of the storage battery changes. It was also found that by applying an AC signal to the storage battery with a higher frequency than the AC frequency corresponding to a zero-crossing point (real component with zero imaginary part) in the complex impedance characteristic, a value corresponding to the dielectric constant of the ferroelectric material can be obtained as the real part of the complex impedance. In this case, by obtaining the dielectric constant of the ferroelectric material from the real part of the complex impedance, the temperature of the storage battery can be estimated from the dielectric constant.

In light of this point, an AC signal of a higher frequency than the AC frequency corresponding to the zero-crossing point in the complex impedance characteristics of the storage battery is applied to the positive and negative electrode layers of the storage battery, and the dielectric constant in the separator is calculated based on the response signal obtained under such conditions. The internal temperature of the storage battery is then monitored based on the calculated dielectric constant. This allows the internal temperature of the storage battery to be suitably detected.

In a tenth aspect, the AC signal application section applies an AC signal in the frequency range of 20 to 800 kHz as the AC signal.

Considering that the AC frequency corresponding to the zero-crossing point in the complex impedance characteristics of a storage battery is, for example, 1 to 10 kHz, the frequency of the AC signal used to calculate the dielectric constant at the separator is set to 20 to 800 kHz. In this case, the situation where the dielectric constant of the separator changes in response to temperature can be properly identified.

In an eleventh aspect, the AC signal application section applies a first frequency AC signal and a second frequency AC signal of a higher frequency than the first frequency, respectively, to measure the complex impedance characteristics near the zero-crossing point, and the calculation section calculates the internal resistance of the storage battery based on the response signal with the AC signal of the first frequency applied, while the dielectric constant in the separator is calculated based on the response signal with the AC signal of the second frequency applied.

The AC signal applying section is designed to apply a first frequency AC signal and a second frequency AC signal of a higher frequency than the first frequency, respectively, for measuring the complex impedance characteristics near the zero-crossing point. Then, the internal resistance of the storage battery is calculated based on the response signal with the AC signal of the first frequency applied, while the dielectric constant at the separator is calculated based on the response signal with the AC signal of the second frequency applied. In this case, the AC frequency that is suitable for calculating the internal resistance of the storage battery and the AC frequency that is suitable for calculating the dielectric constant of the separator can be used separately, and the internal resistance and dielectric constant can be calculated appropriately.

In a twelfth aspect, in the storage battery, the separator undergoes melting when the battery interior reaches a predetermined melting temperature, and in response to the temperature of the storage battery being higher than the predetermined temperature, which is lower than the melting temperature, the calculation section calculates the dielectric constant more frequently than when the temperature is lower than the predetermined temperature.

In a configuration in which a substance (ferroelectric material) whose dielectric constant changes with temperature is added to the separator, the temperature characteristic of the dielectric constant can be used to determine when the internal temperature of the storage battery has reached or approached the melting temperature of the separator. On the other hand, if the dielectric constant is calculated from the complex impedance calculation results, there are concerns about increased computing load and power consumption. In light of this point, in response to the temperature of the storage battery being higher than the predetermined temperature, which is lower than the melting temperature, the frequency of calculation of the dielectric constant is greater than when said temperature is lower than the predetermined temperature. This allows the frequency of dielectric constant calculation to be relatively low in the normal state of the storage battery to reduce the computing load and power consumption, while temporarily increasing the sensitivity of temperature rise detection when there is concern about thermal runaway.

Hereinafter, embodiments will be described with reference to the drawings. In the present embodiment, a lithium-ion battery is used as a secondary battery, and a specific configuration using the lithium-ion battery will be described. It should be noted that in the following embodiments, parts that are the same or equivalent to each other are given the same reference numerals in the drawings, and the explanations of the parts with the same reference numerals are incorporated herein by reference.

### First Embodiment

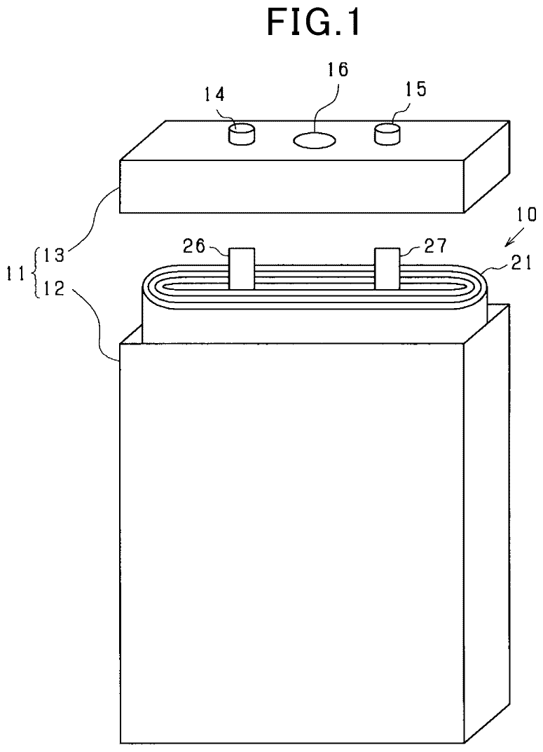

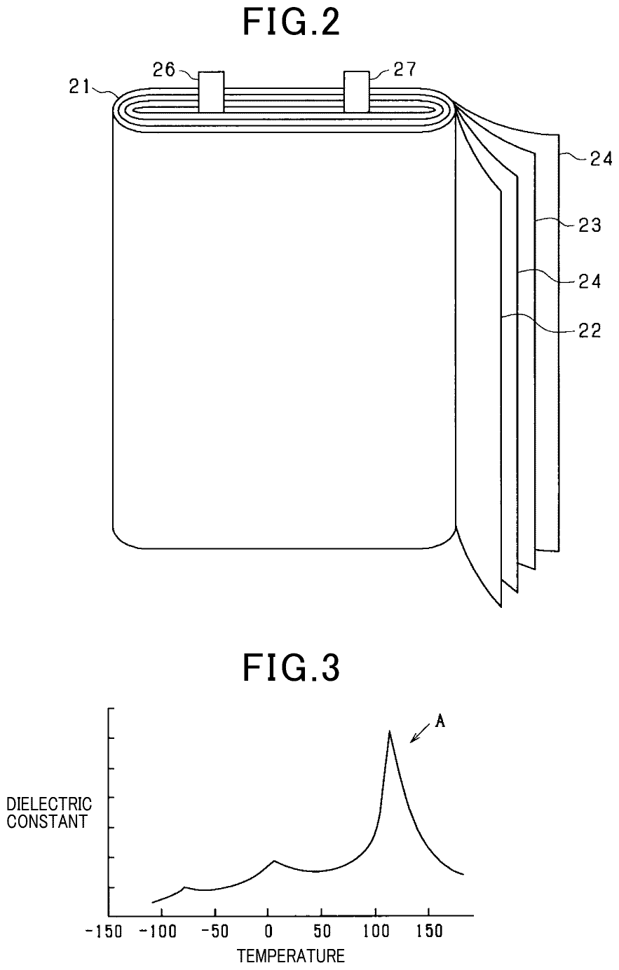

FIG. 1 shows a perspective view of a lithium-ion battery 10, and FIG. 2 shows a perspective view of a wound body 21 constituting the lithium-ion battery 10. Note that in the following description, the lithium-ion storage battery 10 is referred to simply as a storage battery 10.

In FIG. 1, the storage battery 10 includes a case 11 and the wound body 21 accommodated in the case 11. The case 11 has a flat rectangular shape and is made of, for example, metal or resin material. The case 11 has a body 12 and a cover 13 that can be attached to an opening side of the body 12, and the body 12 and the cover 13 form a closed space that accommodates the wound body 21. The wound body 21 is accommodate in the case 11 and is impregnated with an electrolyte. The case 11 is provided with a positive electrode terminal 14 and a negative electrode terminal 15 for external connections and a safety valve 16 that opens and releases internal pressure when the internal pressure of the case 11 rises to a predetermined level.

As shown in FIG. 2, the wound body 21 is configured by laminating of a positive electrode layer 22, a negative electrode layer 23, and a separator 24. Specifically, the positive electrode layer 22, the negative electrode layer 23, and the separator 24 are each formed as a sheet, and they are laminated each other to form a laminated sheet. Then, the laminated sheet consisting of the positive electrode layer 22, the negative electrode layer 23, and the separator 24 is wound into a flat shape to form the wound body 21. In the laminated sheet, the positive electrode layer 22, the separator 24, the negative electrode layer 23, and the separator 24 are laminated in four layers in this order, and the laminated sheet is wound around to form the separator 24 between the positive electrode layer 22 and the negative electrode layer 23.

The positive electrode layer 22 is formed by a positive active material layer consisting of, for example, lithium transition metal oxide. For example, Li (Co⅓Ni⅓Mn⅓) O2, LiNiO2, LiMn2O4, LiCoO2, LiFePO4, etc. can be used as positive active materials. The negative electrode layer 23 is formed by a negative active material layer consisting of, for example, carbon-based material.

The separator 24 is an insulating sheet having ion conductivity. Specifically, the separator is formed by a polyolefin layer, such as polypropylene (PP), polyethylene (PE), or a combination of these compounds.

The wound body 21 is provided with a positive electrode collector 26 made of aluminum foil or the like and a negative electrode collector 27 made of copper foil or the like. When the wound body 21 is accommodated in the case 11, the positive electrode collector 26 is electrically connected to the positive electrode terminal 14 and the negative electrode collector 27 is electrically connected to the negative electrode terminal 15.

By the way, there is concern that the storage battery 10 may experience thermal runaway due to an excessive increase in internal temperature. In this case, as the internal temperature rises, melting of the separator 24, thermal decomposition of the positive electrode layer 22, internal gas generation, and thermal runaway occur in this order. If there is a risk of this thermal runaway occurring, it is desirable to quickly detect the rise in internal temperature in the storage battery 10. Therefore, in the present embodiment, a ferroelectric material is added to the separator 24 of the storage battery 10 as a substance whose dielectric constant changes with temperature, and the internal temperature of the storage battery 10 can be detected by measuring the dielectric constant. In the present embodiment, barium titanate (BaTiO3) is used as the ferroelectric material.

FIG. 3 shows the temperature characteristics of dielectric constant in the ferroelectric material. As shown in FIG. 3, the ferroelectric material has a characteristic in which the dielectric constant reaches a maximum value at several specific temperatures (Curie temperature). In the present embodiment, the separator 24 contains a ferroelectric material, thereby imparting a predetermined temperature characteristic to the separator 24. The ferroelectric material is applied to one or both of front and back seat surfaces of the sheet-like separator 24. Specifically, a particulate ferroelectric material could be adhered to the sheet surface of the separator 24 by coating. It is also possible to have a ferroelectric material buried (contained) inside the separator 24.

Here, in the separator 24, melting occurs when the inside of the battery reaches a predetermined melting temperature (around 120-140° C.). In contrast, the ferroelectric material added to the separator 24 has one of the Curie temperatures at which the electrical conductivity reaches an extreme value, which is the melting temperature of the separator 24 or its vicinity. In FIG. 3, “A” among the multiple maxima is the maximum value corresponding to the melting temperature of the separator 24. In this case, when thermal runaway occurs in the storage battery 10, the internal temperature of the storage battery 10 rises and reaches the melting temperature of the separator 24 or near that temperature, causing a sudden change in the dielectric constant of the storage battery 10 (a sudden change in the capacitor capacity).

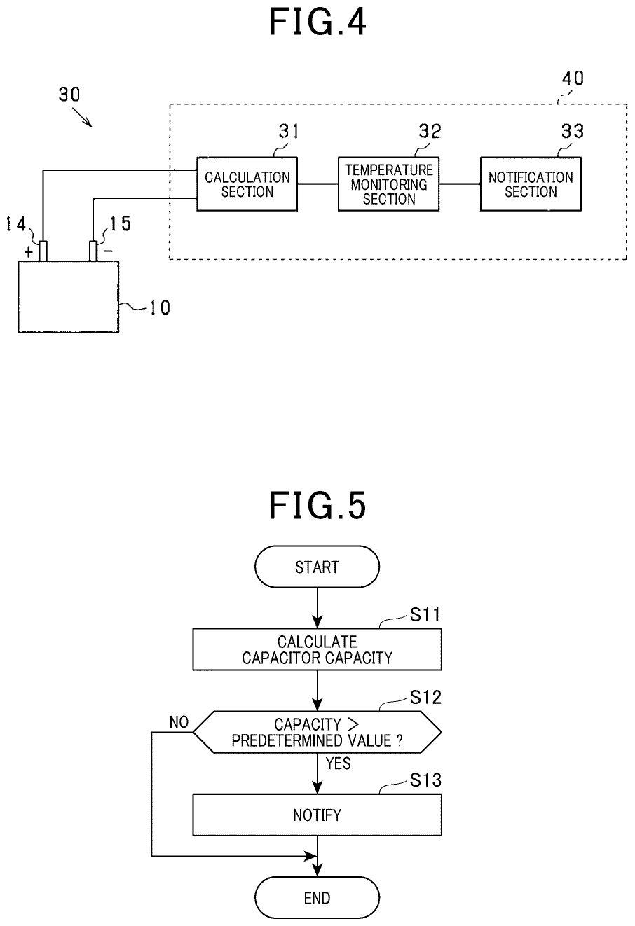

FIG. 4 shows a schematic of a battery unit 30 including the storage battery 10. In FIG. 4, the battery unit 30 is provided with a calculation section 31 that is connected to the positive electrode terminal 14 and the negative electrode terminal 15 of the storage battery 10 and calculates the capacitor capacity of the storage battery 10 using electrical information input from each of these terminals 14 and 15, a temperature monitoring section 32 that monitors the temperature of the storage battery 10 based on the capacitor capacity calculated by the calculation section 31, and a notification section 33 that notifies to the user or others based on the monitoring results by the temperature monitoring section 32. Each of these sections is a processing function realized by a control unit 40, which consists of a microcomputer or the like. The control unit 40 is composed of a microcomputer having a CPU (arithmetic unit) and memory devices (various memories), and realizes various functions by executing programs stored in the memory devices. The various functions may be realized by electronic circuits, which are hardware, or by both hardware and software. The control unit 40 corresponds to a battery monitoring device.

When monitoring the temperature of the storage battery 10, the calculation section 31 applies AC signals to the positive electrode terminal 14 and the negative electrode terminal 15, and calculates the capacitor capacity based on the response signals. In the present embodiment, the electrochemical impedance measurement method (AC impedance method) is used to apply AC voltage to the positive electrode terminal 14 and the negative electrode terminal 15, and based on the frequency characteristics of the complex impedance obtained from the AC voltage and its response signal, the AC current, the capacitor capacity of the storage battery 10 is calculated. Note that it is also possible to apply an alternating current as an AC signal. The dielectric constant can also be calculated by using the correlation between capacitance and dielectric constant.

In addition, based on the capacitor capacity, the temperature monitoring section 32 determines whether the internal temperature of the storage battery 10 has risen to a predetermined temperature (e.g., 120° C.) corresponding to the melting temperature of the separator 24. The notification section 33 notifies the user, for example, by voice, screen display, lamp display, or other means, based on the results of monitoring by the temperature monitoring section 32, that there is a possibility of thermal runaway of the storage battery 10.

FIG. 5 shows a flowchart of a temperature monitoring process for the storage battery 10, and this process is executed by the control unit 40 at a predetermined cycle.

In FIG. 5, in step S11, the capacitor capacity of the storage battery 10 is calculated. At this time, using the AC impedance method as previously described, an AC signal is applied to the positive electrode terminal 14 and the negative electrode terminal 15, and the capacitor capacity is calculated based on the response signal.

Then, in step S12, it is determined whether the internal temperature of the storage battery 10 has risen to a predetermined temperature (e.g., 120° C.) corresponding to the melting temperature of the separator 24, depending on whether the capacitor capacity calculated in step S11 is greater than the predetermined value. At this time, if the capacitor capacity of the storage battery 10 corresponds to the dielectric constant that is the maximum value in the temperature characteristic of dielectric constant, the internal temperature of the storage battery 10 is considered to have risen to the temperature equivalent to the melting temperature of the separator 24, and the determination at step S12 is YES, whereupon the process proceeds to step S13. In step S13, the user and others are notified that there is a possibility of thermal runaway of the storage battery 10.

According to the present embodiment detailed above, the following excellent effects can be obtained.

In the storage battery 10, the separator 24 is provided in a form that includes a substance (ferroelectric material) whose dielectric constant changes in accordance with temperature, making it possible to detect the internal temperature of the storage battery 10 by measuring the dielectric constant or its correlated value, the capacitor capacity, or by other means. In this case, when a temperature change occurs inside the storage battery 10, the temperature change can be directly detected as a change in the dielectric constant inside the battery. As a result, it is possible to realize a storage battery 10 that enables quick detection of the internal temperature.

The storage battery 10 of the present embodiment does not force a change in the electrode material of the storage battery 10 for existing configurations, and can be left as before. Here, the electrode material affects the energy capacity, output density, and performance degradation of a storage battery over time, and since tuning is performed over an enormous amount of development man-hours, it again takes an enormous amount of development work required to maintain the same performance when a new material is added to the electrode material. In contrast, the above disadvantage can be avoided if the separator 24 is configured with ferroelectric material added to it as described above.

By adding a ferroelectric material to the separator 24, the dielectric constant can be increased, and the sensitivity of temperature detection can be improved.

In the separator 24, a ferroelectric material is installed in which the Curie temperature at which the dielectric constant reaches its maximum value is at or near the melting temperature of the separator 24. In this case, by identifying the sudden change in dielectric constant, the situation where thermal runaway of the storage battery 10 may occur can be quickly detected.

By applying an AC signal to the positive electrode layer 22 and negative electrode layer 23 to calculate the capacitor capacity (or dielectric constant) and using that capacitor capacity for battery monitoring, the internal temperature of the storage battery 10 can be suitably determined. In addition, based on the capacitor capacity, since it is determined that the internal temperature of the storage battery 10 has risen to a predetermined temperature which is set as the melting temperature of the separator 24 or a temperature close to that temperature, it makes possible to detect early on the risk of thermal runaway in the storage battery 10 and to take appropriate measures, such as alerting the user.

In contrast to the existing technology, the existing technology required information on the heat inside the battery to be obtained from a temperature sensor outside the battery or a sensor that detects gas pressure or components released outside the battery during thermal runaway. In the present embodiment, in contrast, information about the heat inside the battery can be suitably obtained from the capacitor capacity of the storage battery 10, even without a temperature sensor or gas sensor outside the battery.

### Second Embodiment

In the second embodiment, a storage battery 10 is configured to add ferroelectric material to a separator 24 as previously described. In addition, in the present embodiment, the change in dielectric constant or capacitor capacity corresponding to the internal temperature of the storage battery 10 is especially quantified, and the internal temperature of the storage battery 10 is estimated based on the dielectric constant or capacitance information obtained from the storage battery 10.

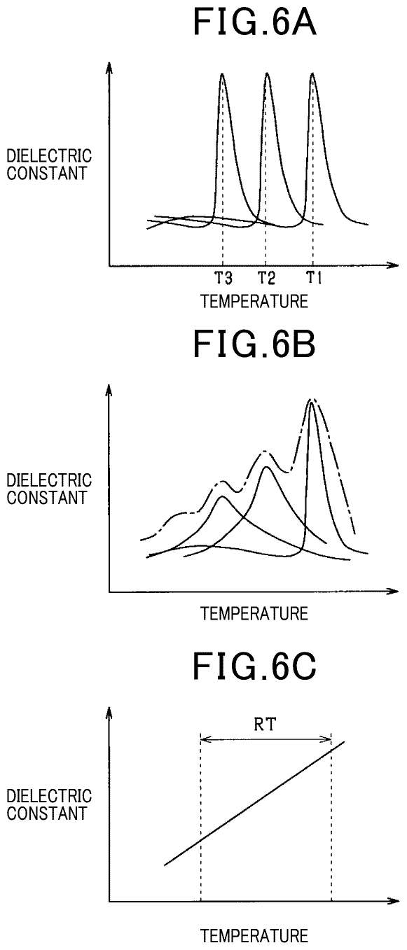

Here, the ferroelectric material to be added to the separator 24 should include several substances with different Curie temperatures at which the dielectric constant reaches its maximum value. As shown in FIG. 6A, this causes the dielectric constant to change to a maximum value in storage battery 10 at different temperatures T1 to T3 for each substance, respectively. In this case, each temperature T1-T3 at which maxima occur should be equally spaced. However, the temperature interval may be narrower at the low temperature side than at the high temperature side. Or vice versa, the temperature interval may be wider at the low temperature side than at the high temperature side. Dielectric maxima may occur at two or four or more temperatures.

In addition, as shown in FIG. 6B, the magnitudes of the maxima are different for each substance, and the characteristics with respect to temperature are smoothed (flattened), and then adjusted so that the temperature characteristics of the composite dielectric constant is obtained by synthesizing the temperature characteristics of each dielectric constant. This adjustment results in the relationship shown in FIG. 6C.

According to FIG. 6C, a unique correlation between temperature and dielectric constant is defined in a given temperature range RT, which includes each of the above temperatures T1 to T3. The temperature range RT should include the operating temperature range in which the storage battery 10 operates. Further, the temperature range RT should include the operating temperature range in which the storage battery 10 operates and the melting temperature of the separator 24. Since dielectric constant and capacitor capacity are in a proportional relationship, it is acceptable to establish a linear correlation between temperature and capacitor capacity.

Note that by mixing additives such as shifters and depressors in ferroelectric material, it is possible to shift the maximum value of dielectric constant to the low temperature side or to flatten the maximum value. As a shifter, for example, it is possible to replace Ba2+ in barium titanate with Sr2+, Ca2+, etc., or Ti4+ with Sn4+, Zr4+, etc. CaTiO3, MgTiO3, etc. can be used as a depressor.

In the present embodiment of a battery unit 30, in FIG. 4, a calculation section 31 calculates the dielectric constant of the storage battery 10. A temperature monitoring section 32 estimates the internal temperature of the storage battery 10 based on the dielectric constant calculated by the calculation section 31, using the relationship shown in FIG. 6C. Further, in the present embodiment, a control unit 40 also calculates a correction value to correct the relationship shown in FIG. 6C under conditions where the internal and external temperatures of the storage battery 10 are the same. Although not shown in the figure, the control unit 40 includes, in addition to the configuration shown in FIG. 4, a temperature determination section and a correction value calculation section.

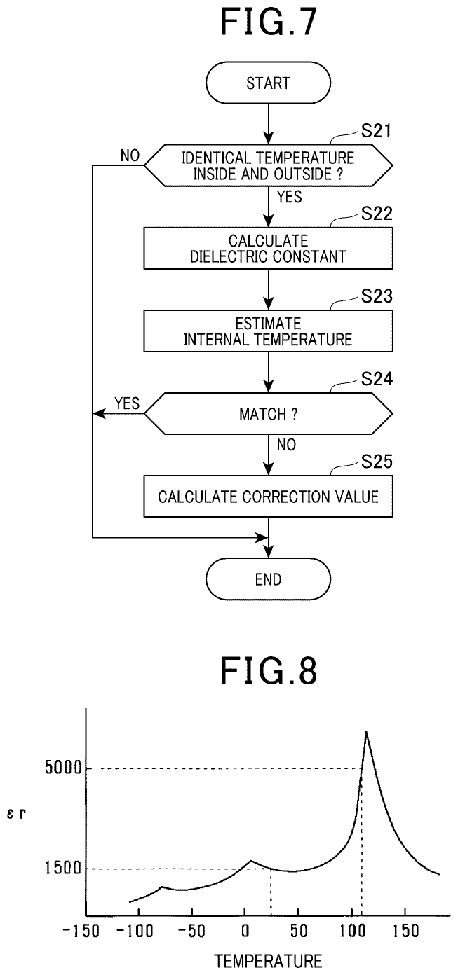

FIG. 7 is a flowchart of a temperature monitoring process in the present embodiment, which shows the process of calculating the correction value, and this process is executed by the control unit 40 at a predetermined cycle.

In FIG. 7, step S21 determines whether the internal temperature of the storage battery 10 and the external temperature outside the storage battery 10 are under the same conditions (temperature determination section). The external temperature may be, for example, the temperature detected by a temperature sensor attached to the outside of the storage battery 10 (outside of a case) or in the environment where the storage battery 10 is installed. For example, in a situation where the storage battery 10 has been left unused for a long time, the internal temperature of the storage battery 10 is the same as the external temperature, and step S21 is answered in the affirmative. If step S21 is YES, the process proceeds to step S22.

In step S22, the dielectric constant of the storage battery 10 is calculated using the AC impedance method as previously described. In the subsequent step S23, the relationship shown in FIG. 6C is used to estimate the internal temperature of the storage battery 10 based on the dielectric constant calculated in step S22.

Then, in step S24, the current external temperature is compared with the estimated internal temperature of the storage battery 10 to determine whether those respective temperatures match, specifically, whether the difference between those respective temperatures is within a predetermined range. If the current external temperature does not match the estimated internal temperature of the storage battery 10, then the process proceeds to step S25 to calculate a correction value to correct the relationship shown in FIG. 6C. This correction value is calculated, for example, as an offset correction value, and is used to correct the estimated internal temperature using the relationship shown in FIG. 6C at the next and subsequent temperature estimation times. Note that the correction values may be stored and retained in a backup memory such as EEPROM. In addition, it may also be configured so that the relationship shown in FIG. 6C is updated by the correction value.

According to the embodiment described in detail above, in the storage battery 10, a plurality of substances with different Curie temperatures are added to the separator 24, thereby making it possible to define a unique correlation between temperature and dielectric constant (or capacitor capacity) within a predetermined temperature range, including between each Curie temperature. By using this correlation, it is possible to estimate the internal temperature of the storage battery 10 based on the dielectric constant.

In the present embodiment, when a temperature change occurs inside the battery, the temperature change can be directly detected. Therefore, unlike existing technology that uses a temperature sensor external to the battery, it is not necessary to wait for heat to be transferred from inside the battery to the outside, thereby reducing discrepancies and time delays in temperature detection.

For example, in a situation where a storage battery 10 has been left for a long time, the 10 internal temperature of the storage battery is the same as the external temperature. In this case, by comparing the internal temperature (estimated temperature) of the storage battery 10 with the external temperature, it is possible to determine the deviation in the correlation between temperature and dielectric constant. In this regard, since the configuration is designed to calculate a correction value to correct the correlation after the temperature comparison as described above, the accuracy of temperature estimation in storage battery 10 can be improved.

In a storage battery 10, wiring is generally connected to a positive electrode terminal 14 and a negative electrode terminal 15, and the voltage between the terminals and the energizing current are measured as appropriate in that condition. In light of this, the calculation of the dielectric constant or capacitor capacity of the storage battery 10 can be easily realized using existing measurement functions. In other words, it is possible to suitably estimate the temperature inside the battery while using the existing configuration.

Incidentally, when a battery module is composed of multiple storage batteries 10 (in other words, when a battery assembly is composed of multiple battery cells as storage batteries 10), a function for measuring terminal-to-terminal voltage and energizing current is provided for each storage battery 10. In this case, by enabling the calculation of the dielectric constant or capacitor capacity of all storage batteries 10 in the battery module, voltage detection, current detection, and internal temperature detection can be realized for all storage batteries (all cells).

### Third Embodiment

In a ferroelectric material added to a separator 24 of a storage battery 10, the relative dielectric constant εr changes as the temperature of the storage battery 10 changes. For example, as shown in FIG. 8, εr could be 1500 when the temperature of the storage battery 10 is 25° C. and εr could be 5000 when the temperature of the storage battery 10 is 110° C. In this case, if the relative dielectric constant εr of the ferroelectric material of the separator 24 is known at the time of use of the storage battery 10, the temperature of the storage battery 10 can be determined. The temperature range corresponding to the εr of the ferroelectric material added to the separator 24 should include the melting temperature of the separator 24 or a temperature near that melting temperature. Note that the dielectric constant & can be used as a parameter instead of the relative dielectric constant εr.

In addition, in the storage battery 10, impedance measurement is performed by applying an AC signal with a frequency of about 1 to 10 kHz, for example. In this case, the internal resistance of the storage battery 10 is calculated by the real part (the real part of the zero-crossing point) whose imaginary part is zero in the complex impedance plane plot (Cole-Cole plot) that shows the frequency characteristics of the storage battery 10. Note that the real part at the zero-crossing point mainly represents the solution resistance, which is the resistance to the transfer of electric charge in the solution in the storage battery 10.

Here, according to the present discloser, it has been confirmed that in the frequency range used to calculate the internal resistance of the storage battery 10 (1 to 10 kHz), there is no difference in the imaginary and real parts of the impedance even if the relative dielectric constant εr of the ferroelectric material of the separator 24 is different. In contrast, it has been confirmed that in a frequency range higher than the frequency range used to calculate the internal resistance, differences occur in the imaginary and real parts of the impedance when the relative dielectric constant εr of the ferroelectric material in the separator 24 is different.

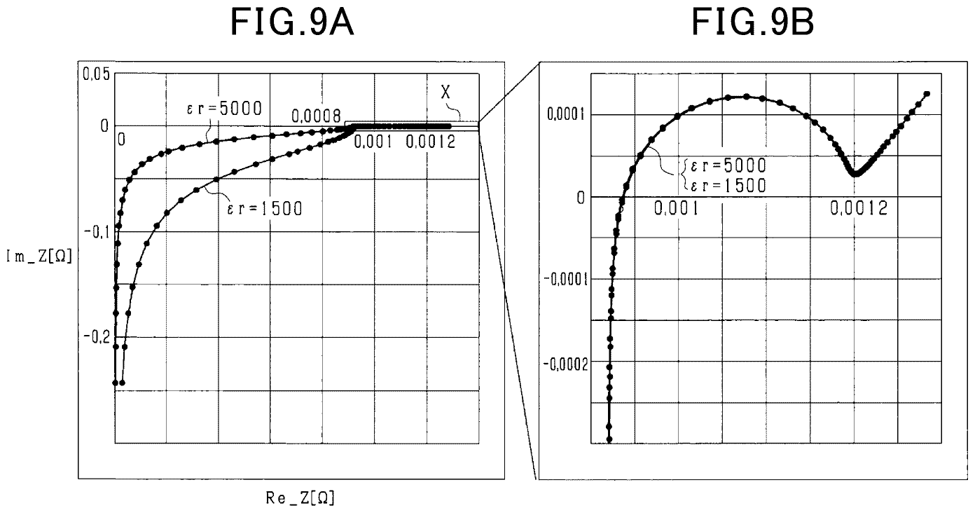

FIG. 9 shows an example of a complex impedance plane plot of a storage battery 10. FIG. 9A shows the impedance characteristics when the frequency is varied from 0.1 Hz to 1 MHz, and FIG. 9B shows an enlarged view of the impedance characteristics of the X portion including the vicinity of the zero-crossing point in FIG. 9A. FIG. 9 shows two characteristics for relative dielectric constant εr of 1500 and 5000.

In FIG. 9B, or the X part of FIG. 9A, there is no difference in impedance characteristics for either εr=1500 or 5000, and the real part Re_Z, calculated as the zero-crossing point, is the same. Note that the real part of the impedance, Re_Z, becomes smaller the higher the frequency applied. In contrast, in FIG. 9A, there is a difference in impedance characteristics between the case with εr=1500 and the case with εr=5000 in the region where the frequency is higher than the X part, and the impedance measurement points are different at each frequency.

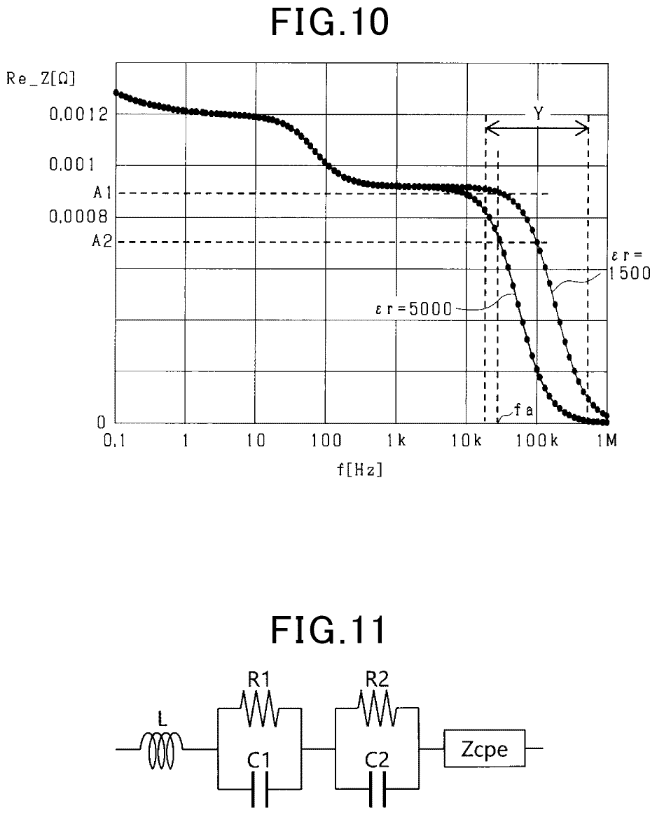

According to FIG. 9A, the relationship in FIG. 10 can be derived as the relationship between the frequency f and the real part Re_Z. In FIG. 10, the real part Re_Z is different in the frequency range Y for εr=1500 and for εr=5000. The frequency range Y is from 20 to 800 kHz. n other words, by applying an AC signal of a predetermined frequency within the frequency range Y to the storage battery 10, a value corresponding to the relative dielectric constant εr of the ferroelectric material in the separator 24 can be derived as the real part Re_Z of the impedance.

For example, when an AC signal of frequency fa (e.g., 40 kHz) within frequency range Y is applied to the storage battery 10, the real part Re_Z becomes A1 if the relative dielectric constant εr is 1500, and the real part Re_Z becomes A2 if the relative dielectric constant εr is 5000. In addition, if the relative dielectric constant εr is between 1500 and 5000, the real part Re_Z is intermediate between A1 and A2.

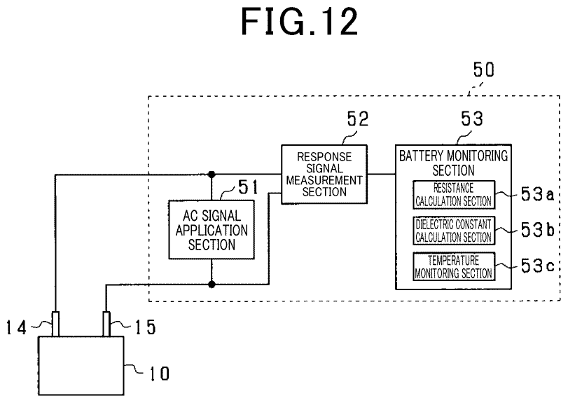

In the present embodiment, a control unit 50 shown in FIG. 12, corresponding to the battery monitoring device, applies an AC signal of a frequency higher than the AC frequency corresponding to the zero-crossing point in the complex impedance characteristic of the storage battery 10, calculates the relative dielectric constant εr in the separator 24 based on the response signal obtained with the AC signal applied, and monitors the internal temperature of the storage battery 10 based on the relative dielectric constant εr. In this case, the control unit 50 analyzes the response signal, the voltage variation, and calculates the real part Re_Z of the impedance. Further, using the relationship in FIG. 10, the relative dielectric constant εr of the ferroelectric material is calculated from the real part Re_Z, and the battery temperature is monitored based on the relative dielectric constant εr. The control unit 50 is composed of a microcomputer having a CPU (arithmetic unit) and memory devices (various memories), and realizes various functions by executing programs stored in the memory devices.

In the present embodiment, an equivalent circuit of the storage battery 10 is assumed to be the configuration shown in FIG. 11. In FIG. 11, L is an inductance of the wound body 21 including the positive current collector 26 and the negative current collector 27, respectively. R1 is a resistance of the electrolyte and C1 is a capacitor component of the ferroelectric material (barium titanate). These R1 and C1 are connected in parallel. In addition, R2 is a composite resistance of the reaction resistance of the positive active material (resistance when intercalating) and the reaction resistance of the negative active material, and C2 is a composite electric capacitance of the electric double layer formed at the interface between the positive active material and the electrolyte and the interface between the negative electrode and the electrolyte. Zcpe is a Constant Phase Element impedance and is defined by the following equation.

$$Z c p e = \frac{1}{{( j ω )}^{p} T} = {Z}^{′} - {Z}^{″} {Z}^{′} = \frac{1}{{ω}^{p} T} ( \frac{π}{2} p ) {Z}^{″} = \frac{1}{{ω}^{p} T} ( \frac{π}{2} p ) \qquad [ Math 1 ]$$

Here, j is an imaginary unit, @ is an angular frequency, p is a CPE index, and Tis a CPE constant.

In FIG. 12, the control unit 50 has an AC signal application section 51, a response signal measurement section 52, and a battery monitoring section 53. The AC signal application section 51 is equipped with an oscillator that generates an AC signal of a predetermined frequency, and applies the AC signal of the predetermined frequency to the positive and negative pole sides of the storage battery 10. In the present embodiment, the AC signal application section 51 applies an AC signal of a predetermined frequency in the frequency range of 1 to 10 kHz to the storage battery 10 when calculating the internal resistance of the storage battery 10, and applies an AC signal of a predetermined frequency in the frequency range of 20 to 800 kHz to the storage battery 10 when monitoring the temperature of the storage battery 10. Note that in the following explanation, the frequency range from 1 to 10 kHz used when calculating the internal resistance of storage battery 10 is also referred to as a first frequency range Y1, and the frequency range from 20 to 800 kHz used when monitoring the temperature of storage battery 10 is also referred to as a second frequency range Y2. The AC signal may be a square or triangular wave, instead of being a sine wave signal.

The response signal measurement section 52 measures the voltage fluctuation, which is information reflecting the impedance of the storage battery 10, as a response signal when an AC signal of a predetermined frequency is applied to the storage battery 10 by the AC signal application section 51.

The battery monitoring section 53 calculates the internal resistance and dielectric constant εr of the storage battery 10 as battery parameters indicating the state of the storage battery 10 based on the response signal (voltage variation) measured by the response signal measurement section 52. Specifically, in the battery monitoring section 53, when an AC signal of a predetermined frequency in the first frequency range Y1 is applied, a resistance calculation section 53a calculates the real part Re_Z of the impedance as the internal resistance of the storage battery 10 based on the voltage fluctuation measured by the response signal measurement section 52 and the amplitude of the AC current flowing through the storage battery 10 when the AC signal is applied.

In addition, when an AC signal of a predetermined frequency in the second frequency range Y2 is applied, a dielectric constant calculation section 53b calculates the real part Re_Z of the impedance based on the voltage fluctuation measured by the response signal measurement section 52 and the amplitude of the AC current flowing through the storage battery 10 when the AC signal is applied, and calculates the relative dielectric constant εr of the ferroelectric material from the real part Re_Z. Further, a temperature monitoring section 53c also monitors whether the storage battery 10 is over-temperature based on the relative dielectric constant εr.

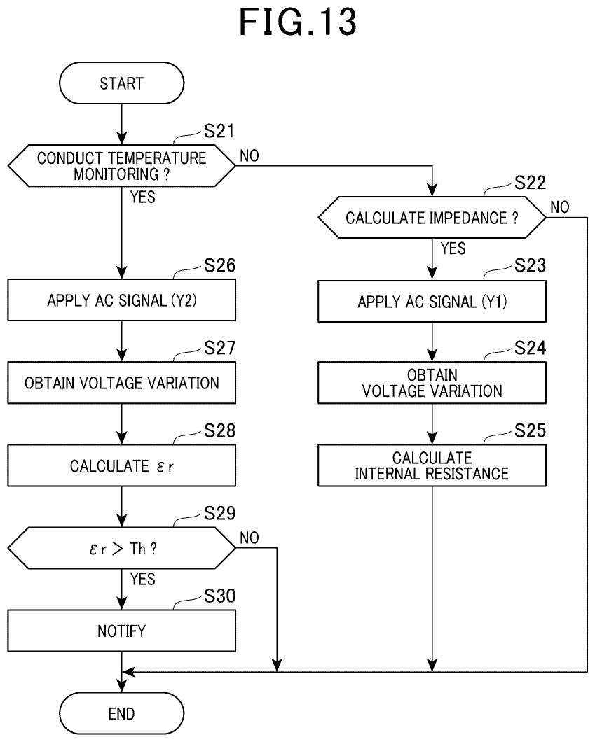

FIG. 13 shows a flowchart of a temperature monitoring process for the storage battery 10, and this process is executed by the control unit 50 at a predetermined cycle.

In FIG. 13, step S21 determines whether an implementation condition for conducting temperature monitoring of the storage battery 10 is met at this moment. This implementation condition is a condition for calculating the relative dielectric constant εr of the storage battery 10, and should be a condition that is satisfied at a predetermined cycle, for example, while the vehicle is running (IG on) or after the vehicle stops running (IG off). The predetermined cycle is, for example, a cycle of every few seconds, a cycle of every few hundreds of milliseconds, or a cycle of every few tens of milliseconds.

If the implementation condition for the temperature monitoring is not met, the process proceeds to step S22. In step S22, it is determined whether it is time to calculate impedance.

For example, immediately after the vehicle's IG is turned on, step S22 may be YES as the impedance calculation condition is satisfied. If step S22 is YES, the process proceeds to step S23 to apply an AC signal of a predetermined frequency in the first frequency range Y1 to the storage battery 10. Then, in step S24, the voltage variation to the AC signal is obtained as a response signal, and in the subsequent step S25, the real part Re_Z of the impedance is calculated based on the voltage variation as the internal resistance of storage battery 10.

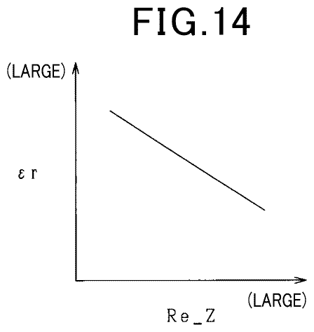

In addition, if step S21 is YES, the process proceeds to step S26 to apply an AC signal of a predetermined frequency in the second frequency range Y2 to the storage battery 10. Then, in step S27, the voltage variation to the AC signal is obtained as a response signal. In the subsequent step S28, the real part Re_Z of the impedance is calculated based on the voltage variation, and the relative dielectric constant εr of the ferroelectric material is calculated based on the real part Re_Z. At this time, it is preferable to determine the relationship shown in FIG. 14 as the relationship between the real part Re_Z of the impedance and the relative dielectric constant εr, and to calculate the relative dielectric constant εr of the ferroelectric material from the real part Re_Z using this relationship.

Then, in step S29, it is determined whether the relative dielectric constant εr calculated in step S28 is greater than a predetermined threshold value Th. The threshold value Th is defined as a value corresponding to the melting temperature of the separator 24. According to step S29, it is determined whether the internal temperature of the storage battery 10 has risen to the melting temperature of the separator 24 (e.g., 120° C.) or a temperature near the melting temperature (e.g., 110° C.). At this time, if the relative dielectric constant εr is greater than the threshold value Th, the internal temperature of the storage battery 10 is considered to have risen to a temperature equivalent to the melting temperature of the separator 24, and the determination at step S29 is YES, whereupon the process proceeds to step S30. In step S30, the user and others are informed of the possibility of thermal runaway of the storage battery 10.

According to the third embodiment described above, the following effects are achieved in addition to the previously mentioned effects.

An AC signal of a higher frequency than the AC frequency corresponding to the zero-crossing point in the complex impedance characteristic is applied to the storage battery 10, and the relative dielectric constant εr in the separator 24 is calculated based on the response signal obtained in that condition. The internal temperature of the storage battery 10 is then monitored based on the calculated relative dielectric constant εr. This makes it possible to appropriately detect the internal temperature of the storage battery 10.

The AC signal application section 51 is configured to apply an AC signal of the first frequency (frequency within the first frequency range Y1) and an AC signal of the second frequency (frequency within the second frequency range Y2), which is higher than the first frequency, to measure the complex impedance characteristics near the zero-crossing point. The internal resistance of the storage battery 10 is then calculated based on the response signal with the AC signal of the first frequency applied, while the relative dielectric constant εr at the separator 24 is calculated based on the response signal with the AC signal of the second frequency applied. In this case, the AC frequency that is suitable for calculating the internal resistance of the storage battery 10 and the AC frequency that is suitable for calculating the relative dielectric constant εr of the separator 24 can be used differently, and the internal resistance and relative dielectric constant εr can be calculated appropriately.

### Other Embodiments

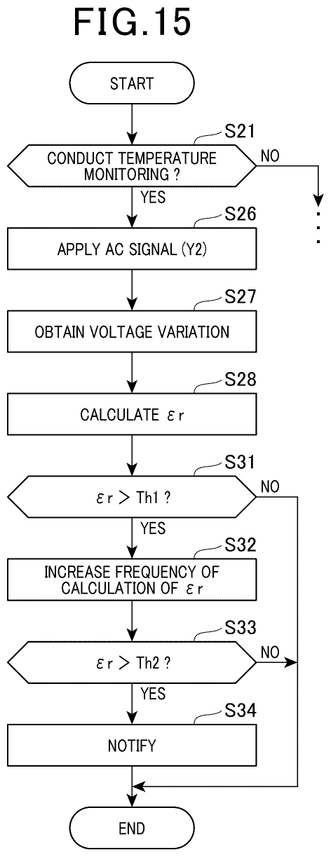

Each of the above embodiments may be modified, for example, as follows
The ferroelectric material added to the separator 24 in the storage battery 10 may have a dielectric constant that reaches an extreme value at a predetermined low temperature (e.g., −10° C.). In this case, the control unit 40 (temperature monitoring section) determines that the internal temperature of the storage battery 10 has dropped to low temperature based on the dielectric constant or capacitor capacity. This makes it possible, for example, to monitor the frequency of use of the storage battery 10 in low temperature conditions as a usage condition.
In the third embodiment, the frequency of the AC signal is 1 to 10 kHz when calculating the internal resistance of the storage battery 10, and the frequency of the AC signal is 20 to 800 kHz when monitoring the temperature of the storage battery 10, however, these can be changed. For example, when monitoring the temperature of storage battery 10, the frequency of the AC signal should be higher than when calculating the internal resistance of storage battery 10, for example, 10 kHz or higher.
When the temperature of the storage battery 10 is higher than the predetermined temperature, which is lower than the melting temperature of the separator 24, the configuration may be made to increase the frequency of calculation of the relative dielectric constant εr compared to when the temperature is lower than the predetermined temperature. Specifically, the control unit 50 may perform a process in FIG. 15. FIG. 15 is a partially modified version of the flowchart in FIG. 13, with the same step numbers for identical processes.

In FIG. 15, step S28 calculates the relative dielectric constant εr of the ferroelectric material based on the voltage variation in response to the AC signal. Then, in step S31, it is determined whether the relative dielectric constant εr calculated in step S28 is greater than a predetermined first threshold value Th1. The first threshold value Th1 is defined as a value corresponding to a predetermined temperature (e.g., 70° C.) lower than the melting temperature (120° C.) of the separator 24. In addition, the first threshold value Th1 should be the upper temperature of the storage battery 10 during normal use or a temperature higher than that upper temperature. At this time, if the relative dielectric constant εr is less than or equal to the first threshold value Th1, this process is terminated once, and if the relative dielectric constant εr is greater than the first threshold value Th1, the process proceeds to step S32.

In step S32, the frequency of calculation of the relative dielectric constant εr is determined to be larger than in the normal case (i.e., when εr≤Th1) in the next and subsequent temperature monitoring processes. For example, the frequency of calculation of the relative dielectric constant εr should be n times the normal frequency (n is two or more). This increases the frequency at which the relative dielectric constant εr is calculated in the next temperature monitoring process in accordance with the affirmative decision in step S21.

Then, in step S33, it is determined whether the relative dielectric constant εr is greater than a predetermined second threshold value Th2. The second threshold value Th2 is defined as a value greater than the first threshold value Th1 and corresponding to the melting temperature of the separator 24. Then, if the relative dielectric constant εr is greater than the second threshold value Th2, the internal temperature of the storage battery 10 is considered to have risen to a temperature equivalent to the melting temperature of the separator 24, and the process proceeds to step S34. In step S34, the user and others are informed that thermal runaway of the storage battery 10 may occur.

According to the above configuration, the frequency of calculating the relative dielectric constant εr is relatively low in the normal state of the storage battery 10 to reduce the calculation load and power consumption, while the detection sensitivity of temperature rise can be temporarily increased when concerns about thermal runaway arise.
In addition to barium titanate, lead titanate, potassium niobate, lithium niobate, lead niobate, barium strontium niobate, lithium tantalate, potassium sodium tartrate (Rochelle salt), potassium dihydrogen phosphate, and glycine trisulfide can be used as ferroelectric materials. In addition to ferroelectric material, it is also possible to use paraelectric materials as materials whose dielectric constant changes with temperature. For example, magnesium titanate, calcium titanate, titanium dioxide (especially rutile type), strontium titanate, forsterite (2MgO—SiO2), steatite (MgO—SiO2), and other paraelectric materials can be used.
In the present embodiments disclosed above, the present disclosure is described for can-type lithium-ion batteries, however, it can alternatively be applied to laminated lithium-ion batteries. In addition, the present disclosure can also be applied to nickel-metal hydride batteries, etc., as storage batteries other than lithium-ion storage batteries.

The control unit and its methods described in the present disclosure may be realized by a dedicated computer provided by configuring a processor and memory programmed to perform one or more functions embodied by a computer program. Alternatively, the control unit and its methods described in the present disclosure may be realized by a dedicated computer provided by configuring the processor with one or more dedicated hardware logic circuits. Alternatively, the control unit and its methods described in the present disclosure may be realized by one or more dedicated computers composed of a processor and memory programmed to perform one or more functions, in combination with a processor composed of one or more hardware logic circuits. In addition, the computer program may also be stored in a computer-readable, non-transitory storage media as instructions to be executed by a computer.

Although the present disclosure has been described in accordance with embodiments, it is understood that the present disclosure is not limited to the embodiments or structures. The present disclosure also encompasses various variants and variations within the scope of equality. In addition, various combinations and forms, as well as other combinations and forms that include only one element, more or less, thereof, also fall within the scope and idea of the present disclosure.

The technical ideas extracted from the above embodiments are described below.

### [Configuration 1]

A storage battery including:
a positive electrode layer,
a negative electrode layer, and
a separator disposed between the positive electrode layer and the negative electrode layer, wherein
the separator is provided in a form that includes a substance whose dielectric constant changes in response to temperature.

### [Configuration 2]

The storage battery according to configuration 1, wherein
a ferroelectric material is used as the substance.

### [Configuration 3]

The storage battery according to configuration 1, wherein
the separator undergoes melting when the temperature inside the battery reaches a predetermined melting temperature, and
the substance is a ferroelectric material whose Curie temperature, at which the dielectric constant reaches its maximum value, is at or near the melting temperature of the separator.

### [Configuration 4]

A battery unit including:
a storage battery including a positive electrode layer, a negative electrode layer, and a separator disposed between the positive electrode layer and the negative electrode layer, wherein the separator is provided in a form that includes a substance whose dielectric constant changes in response to temperature,
a calculation section that is configured to apply an AC signal to the positive electrode layer and the negative electrode layer and calculates the dielectric constant or capacitor capacity based on the response signal, and
a temperature monitoring section that is configured to monitor the internal temperature of the storage battery based on the dielectric constant or capacitor capacity calculated by the calculation section.

### [Configuration 5]

The battery unit according to configuration 4, wherein
in the storage battery, the separator undergoes melting when the battery interior reaches a predetermined melting temperature,
as the substance, a ferroelectric material is used whose Curie temperature at which the dielectric constant is a maximum value is the melting temperature of the separator or a temperature near the melting temperature of the separator, and
the temperature monitoring section is configured to determine, based on the dielectric constant or capacitor capacity calculated by the calculation section, that the internal temperature of the storage battery has risen to a predetermined temperature determined as the melting temperature of the separator or a temperature near the melting temperature of the separator.

### [Configuration 6]

The battery unit according to configuration 4, wherein
in the storage battery, the substance includes a plurality of substances with different Curie temperatures at which the dielectric constant is maximized, and a unique correlation between temperature and dielectric constant or capacitance is defined within a predetermined temperature range including between the Curie temperatures of each of the substances, and
the temperature monitoring section estimates the internal temperature of the storage battery based on the dielectric constant or capacitor capacity calculated by the calculation section using the correlation.

### [Configuration 7]

The battery unit according to configuration 6, the battery unit further includes:
a temperature determination section configured to determine that the internal temperature of the storage battery and the external temperature outside the storage battery are the same under the same circumstances, and
a correction value calculation section that, when it is determined that a situation exists in which the temperature of the storage battery and the external temperature are the same, calculates a correction value for correcting the correlation by comparing the external temperature in that situation with the internal temperature of the storage battery estimated by the temperature monitoring section.

### [Configuration 8]

A battery monitoring device applicable to a storage battery having a positive electrode layer, a negative electrode layer, and a separator disposed between the positive electrode layer and the negative electrode layer, wherein the separator is provided in a form that includes a substance whose dielectric constant changes in response to temperature, the battery monitoring device including:
a calculation section that is configured to apply an AC signal to the positive electrode layer and the negative electrode layer and calculates the dielectric constant or capacitor capacity based on the response signal, and
a temperature monitoring section that is configured to monitor the internal temperature of the storage battery based on the dielectric constant or capacitor capacity calculated by the calculation section.

### [Configuration 9]

A battery monitoring device applicable to a storage battery having a positive electrode layer, a negative electrode layer, and a separator disposed between the positive electrode layer and the negative electrode layer, wherein the separator is provided in a form that includes a substance whose dielectric constant changes in response to temperature, the battery monitoring device including:
an AC signal application section that is configured to apply an AC signal to the positive electrode layer and the negative electrode layer of the storage battery at a frequency higher than the AC frequency corresponding to a zero-crossing point where an imaginary part becomes zero in the complex impedance characteristic of the storage battery,
a calculation section that is configured to calculate the dielectric constant at the separator based on the response signal while the AC signal is applied by the AC signal application section, and
a temperature monitoring section that is configured to monitor the internal temperature of the storage battery based on the dielectric constant calculated by the calculation section.

### [Configuration 10]

The battery monitoring device according to configuration 9, wherein
the AC signal application section applies an AC signal in the frequency range of 20 to 800 kHz as the AC signal.

### [Configuration 11]

The battery monitoring device according to configuration 9, wherein
the AC signal application section applies a first frequency AC signal and a second frequency AC signal of a higher frequency than the first frequency, respectively, to measure the complex impedance characteristics near the zero-crossing point, and
the calculation section calculates the internal resistance of the storage battery based on the response signal with the AC signal of the first frequency applied, while the dielectric constant in the separator is calculated based on the response signal with the AC signal of the second frequency applied.

### [Configuration 12]

The battery monitoring device according to configuration 9, wherein
in the storage battery, the separator undergoes melting when the battery interior reaches a predetermined melting temperature, and
in response to the temperature of the storage battery being higher than the predetermined temperature, which is lower than the melting temperature, the calculation section calculates the dielectric constant more frequently than when the temperature is lower than the predetermined temperature.

What is claimed is:

1. A storage battery comprising:
a positive electrode layer,
a negative electrode layer, and
a separator disposed between the positive electrode layer and the negative electrode layer, wherein
the separator is provided in a form that includes a substance whose dielectric constant changes in response to temperature.

2. The storage battery according to claim 1, wherein
a ferroelectric material is used as the substance.

3. The storage battery according to claim 1, wherein
the separator undergoes melting when the temperature inside the battery reaches a predetermined melting temperature, and
the substance is a ferroelectric material whose Curie temperature, at which the dielectric constant reaches its maximum value, is at or near the melting temperature of the separator.

4. A battery unit comprising:
a storage battery having a positive electrode layer, a negative electrode layer, and a separator disposed between the positive electrode layer and the negative electrode layer, wherein the separator is provided in a form that includes a substance whose dielectric constant changes in response to temperature,
a calculation section that is configured to apply an AC signal to the positive electrode layer and the negative electrode layer and calculates the dielectric constant or capacitor capacity based on the response signal, and
a temperature monitoring section that is configured to monitor the internal temperature of the storage battery based on the dielectric constant or capacitor capacity calculated by the calculation section.

5. The battery unit according to claim 4, wherein
in the storage battery, the separator undergoes melting when the battery interior reaches a predetermined melting temperature,
as the substance, a ferroelectric material is used whose Curie temperature at which the dielectric constant is a maximum value is the melting temperature of the separator or a temperature near the melting temperature of the separator, and
the temperature monitoring section is configured to determine, based on the dielectric constant or capacitor capacity calculated by the calculation section, that the internal temperature of the storage battery has risen to a predetermined temperature determined as the melting temperature of the separator or a temperature near the melting temperature of the separator.

6. The battery unit according to claim 4, wherein
in the storage battery, the substance includes a plurality of substances with different Curie temperatures at which the dielectric constant is maximized, and a unique correlation between temperature and dielectric constant or capacitance is defined within a predetermined temperature range including between the Curie temperatures of each of the substances, and
the temperature monitoring section estimates the internal temperature of the storage battery based on the dielectric constant or capacitor capacity calculated by the calculation section using the correlation.

7. The battery unit according to claim 6, the battery unit further includes:
a temperature determination section configured to determine that the internal temperature of the storage battery and the external temperature outside the storage battery are the same under the same circumstances, and
a correction value calculation section that, when it is determined that a situation exists in which the temperature of the storage battery and the external temperature are the same, calculates a correction value for correcting the correlation by comparing the external temperature in that situation with the internal temperature of the storage battery estimated by the temperature monitoring section.

8. A battery monitoring device applicable to a storage battery having a positive electrode layer, a negative electrode layer, and a separator disposed between the positive electrode layer and the negative electrode layer, wherein the separator is provided in a form that includes a substance whose dielectric constant changes in response to temperature, the battery monitoring device comprising:
a calculation section that is configured to apply an AC signal to the positive electrode layer and the negative electrode layer and calculates the dielectric constant or capacitor capacity based on the response signal, and
a temperature monitoring section that is configured to monitor the internal temperature of the storage battery based on the dielectric constant or capacitor capacity calculated by the calculation section.

9. A battery monitoring device applicable to a storage battery having a positive electrode layer, a negative electrode layer, and a separator disposed between the positive electrode layer and the negative electrode layer, wherein the separator is provided in a form that includes a substance whose dielectric constant changes in response to temperature, the battery monitoring device comprising:
an AC signal application section that is configured to apply an AC signal to the positive electrode layer and the negative electrode layer of the storage battery at a frequency higher than the AC frequency corresponding to a zero-crossing point where an imaginary part becomes zero in the complex impedance characteristic of the storage battery,
a calculation section that is configured to calculate the dielectric constant at the separator based on the response signal while the AC signal is applied by the AC signal application section, and
a temperature monitoring section that is configured to monitor the internal temperature of the storage battery based on the dielectric constant calculated by the calculation section.

10. The battery monitoring device according to claim 9, wherein
the AC signal application section applies an AC signal in the frequency range of 20 to 800 kHz as the AC signal.

11. The battery monitoring device according to claim 9, wherein
the AC signal application section applies a first frequency AC signal and a second frequency AC signal of a higher frequency than the first frequency, respectively, to measure the complex impedance characteristics near the zero-crossing point, and
the calculation section calculates the internal resistance of the storage battery based on the response signal with the AC signal of the first frequency applied, while the dielectric constant in the separator is calculated based on the response signal with the AC signal of the second frequency applied.

12. The battery monitoring device according to claim 9, wherein
in the storage battery, the separator undergoes melting when the battery interior reaches a predetermined melting temperature, and
in response to the temperature of the storage battery being higher than the predetermined temperature, which is lower than the melting temperature, the calculation section calculates the dielectric constant more frequently than when the temperature is lower than the predetermined temperature.
